(19) United States
(12) Patent Application Publication
(10) Pub. No.: US 2023/0232633 A1
(43) Pub. Date: Jul. 20, 2023

(54) VERTICAL WORDLINE DRIVER STRUCTURES AND METHODS

(71) Applicant: Intel NDTM US LLC, Santa Clara, CA (US)

(72) Inventors: David S. MEYAARD, Boise, ID (US); Nadia M. RAHHAL-ORABI, Cupertino, CA (US); Randy J. KOVAL, Albuquerque, NM (US)

(21) Appl. No.: 18/188,391

(22) Filed: Mar. 22, 2023

(51) Int. Cl. H10B 43/40; H10B 41/41

(52) U.S. Cl. CPC H10B 43/40; H10B 41/41; G11C 16/08

(57) ABSTRACT

Vertical wordline driver structures and methods. The vertical wordline driver comprises a transistor that is used to drive a wordline in a three-dimensional 3D memory structure. A vertical transistor structure is formed in a semiconductor substrate comprising a gate all around (GAA) structure or a double-gate structure including a gate oxide, an amorphous IGZO (Indium Gallium Zinc Oxide) channel, adjacent to the gate oxide, and a liner adjacent to the amorphous IGZO channel. The GAA structure may comprise a conical frustrum shape or a cylindrical shape with straight walls. The double-gate structure may have straight or angled walls. An outer wall of the gate oxide is in contact with a polysilicon gate layer. An upper and lower contact is electrically coupled to the amorphous IGZO channel.

### BACKGROUND INFORMATION

A flash memory device may comprise a memory array that includes a large number of non-volatile memory cells arranged in arrays of rows and columns. In recent years, vertical memory, such as three-dimensional (3D) memory, has been developed in various forms, such as NAND, NOR, cross-point, or the like. A 3D flash memory array may include a plurality of memory cells stacked over one another. Each group of memory cells may share a plurality of access lines, known as wordlines and bitlines.

In NAND memory technology, particularly in 3D NAND memory technology, connection between wordline driver transistors and respective wordlines is an important architecture decision, which affects the 3D NAND die area, die performance and system metrics. Wordline driver transistors need to support high voltages and break down condition and occupy a significant area of the 3D NAND die. The memory tile-based architecture on 3D NAND further increases the total wordline driver area in the die. In general, disposition of the wordline driver transistors affects the contact area availability and block height dimensions in a flash memory device.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIG. 1 is a block diagram of an example of a system that stores data in Non-volatile (NV) media;

FIG. 2 is a block diagram of an example of system including a three-dimensional (3D) memory device structure;

FIG. 3 is a diagram illustrating elevation and plan cross-section views of a transistor gate structure comprising a gate all around (GAA) thin film transistor (TFT) structure, according to a first embodiment;

FIG. 3a is a diagram illustrating cross-section views of a transistor gate structure comprising a double gate, according to a second embodiment;

FIG. 3b is a diagram illustrating an elevation cross-section views of transistor device having similar structures to that shown in FIG. 3, but having first alternative top/drain contact pattern, according to one embodiment;

FIG. 3c is a diagram illustrating an elevation cross-section views of transistor device having similar structures to that shown in FIG. 3b, with an alternative pad material of copper or polysilicion, according to one embodiment;

FIG. 3d is a diagram illustrating cross-section views of a transistor gate structure comprising a double gate that includes an IGZO fill, according to one embodiment;

FIGS. 4a-4h show elevation cross-section views of a semiconductor structure after respective steps is a fabrication process, according to one embodiment;

FIG. 5 is a flowchart illustrating steps performed to obtain the semiconductor structure shown in FIG. 4a;

FIG. 6 is a flowchart illustrating operations performed during steps to obtain the semiconductor structures shown in FIGS. 4b-4h;

FIG. 7a is a diagram illustrating elevation cross-section views of a semiconductor structure including two GAA TFT devices having a first alternative configuration, according to one embodiment;

FIG. 7b is a diagram illustrating a cross-section view of the semiconductor device of FIG. 7a showing further details of the vertical wordline drivers connecting to respective wordlines, according to one embodiment;

FIG. 7c is a diagram illustrating a plan view above the cross-section view of FIG. 7b;

FIG. 7d is a diagram illustrating a cross-sectional view of a portion of a semiconductor structure that includes double gate transistor devices having a pillar structure employing an amorphous IGZO core, according to one embodiment;

FIG. 8a is a diagram illustrating elevation cross-section views of a semiconductor structure including two GAA TFT devices having a second alternative configuration, according to one embodiment;

FIG. 8b is a diagram illustrating a cross-section view of the semiconductor device of FIG. 8a showing further details of the vertical wordline drivers connecting to respective wordlines, according to one embodiment;

FIG. 9a is a diagram illustrating elevation cross-section views of a semiconductor structure including two GAA TFT devices having a third alternative configuration, according to one embodiment;

FIG. 9b is a diagram illustrating a cross-section view of the semiconductor device of FIG. 9a showing further details of the vertical wordline drivers connecting to respective wordlines, according to one embodiment;

FIG. 10 is a diagram illustrating a cross-section view of a transistor structure including a TiN bottom plug contact; and

FIG. 11 is a diagram illustrating a 3D view of an abstracted memory device in which aspect of the embodiments described and illustrated herein may be implemented, according to one embodiment.

### DETAILED DESCRIPTION

Embodiments of vertical wordline driver structures and methods are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

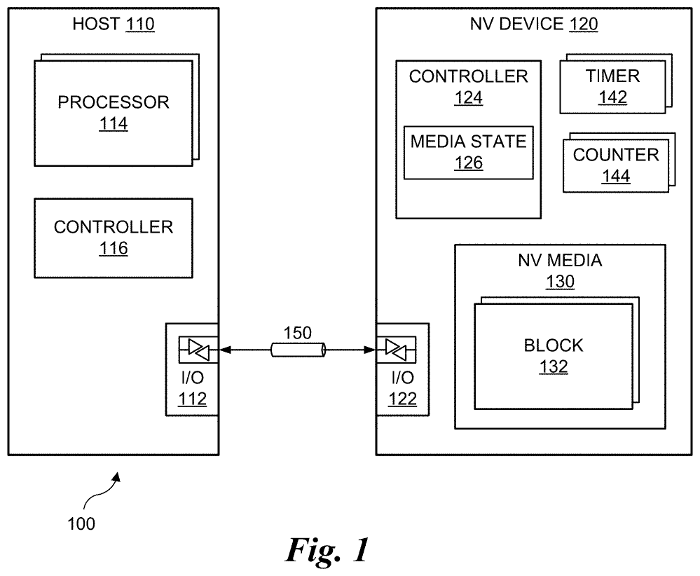

FIG. 1 is a block diagram of an example of a system that stores data in Non-volatile (NV) media. System 100 includes host 110 coupled to NV device 120. Host 110 represents a computing device. Host 110 includes I/O (input/output) 112, which represents hardware to interconnect with NV device 120. NV device 120 includes I/O 122 which corresponds to I/O 112. I/O 122 represents hardware to interconnect with host 110.

Host 110 provides a hardware platform to operate NV device 120. Host 110 includes one or more processors 114 to perform the operations of host 110. Processor 114 executes a host operating system (OS) that provides a software platform for the operation of NV device 120. The hardware platform provides hardware resources to interface with NV device 120 including transceiver hardware to perform access to the device. The software platform includes control software to execute other software elements such as applications or other agents that execute under the OS and create requests to access NV device 120.

I/O 112 and I/O 122 interconnect through one or more signal lines 150. Signal lines 150 typically include multiple separate lines and can be considered one or more buses to connect host 110 to NV device 120. Host 110 can send a host read command over signal line 150 to NV device 120. In response to the read command, NV device 120 services the request out of a transient Vt state, in accordance with any example provided.

In one example, host 110 includes controller 116. Controller 116 represents a memory controller or storage controller. In one example, controller 116 is integrated with processor 114. In one example, controller 116 is separate from processor 114. Controller 116 enables host 110 to manage access to NV device 120. In response to host operations by processor 114 that request access to data on NV device 120, controller 116 provides access to NV device 120. Controller 116 can represent hardware and firmware elements of host 110 to enable interaction with NV device 120.

NV device 120 includes controller 124, which represents a storage controller at the side of the storage device, which is separate from controller 116 of host 110. Controller 116 of host 110 represents components of the host system. Controller 124 represents components of the storage device or memory device into which the NV media is incorporated. Controller 124 receives commands send from host 110 and determines how to service the command or request from the host. Controller 124 performs operations to access (e.g., read or write) NV media 130 in response to the host command.

NV media 130 represents a nonvolatile storage media of NV device 120. In one example, NV media 130 includes three-dimensional (3D) NAND (not AND) memory cells. In one example, NV media 130 includes 3D NOR memory cells. In one example, NV media 130 includes 3D crosspoint memory cells.

NV media 130 includes bitcells or memory cells organized as blocks 132. A block of memory refers to a portion of NV media 130 that is jointly charged or activated for an access operation. In one example, blocks 132 are subdivided as subblocks. In one example, a block refers to bitcells that share a select gate line. In one example, multiple subblocks share a select gate (e.g., a common select gate source (SGS) or a common select gate drain (SGD)) connector.

In one example, a block refers to an erase unit, or a unit size of NV media 130 that is erased together and monitored by controller 124 for number of writes. In one example, NV media 130 includes single level cell (SLC) and multilevel cell (MLC) media. For example, NV media 130 can include SLC and QLC (quad level cell) or SLC and TLC (triple level cell) bitcells. The block size could be different depending on the media type.

In one example, controller 124 is an ASIC (application specific integrated circuit) that controls operation of NV device 120. In one example, controller 124 is a CPU (central processing unit) core or processor device on NV device 120. In one example, NV device 120 represents an SSD and controller 124 controls multiple NV media dies or NV media chips integrated into the SSD. In one example, NV device 120 represents a module or PCB (printed circuit board) that includes multiple NV media dies or NV media chips integrated onto it and controller 124 controls the NV media dies of the module. In one example, controller 124 executes firmware to manage NV device 120. In one example, controller 124 executes firmware to manage NV device 120, including firmware to control the servicing of a read command based on whether the NV media is in thermal equilibrium.

In one example, controller 124 manages Vt state detection and read command servicing based on idle time or delay between consecutive read commands. In one example, controller 124 monitors one or more media states 126. Media state 126 represents a state of a portion of memory (such as a block) and can determine how to access the media based on media state 126. For example, if media state 126 indicates that a target block is in a stable state, controller 124 can first issue a dummy read prior to accessing the target block. In one example NV media devices 120 may include one or more timers 142 and counters 144.

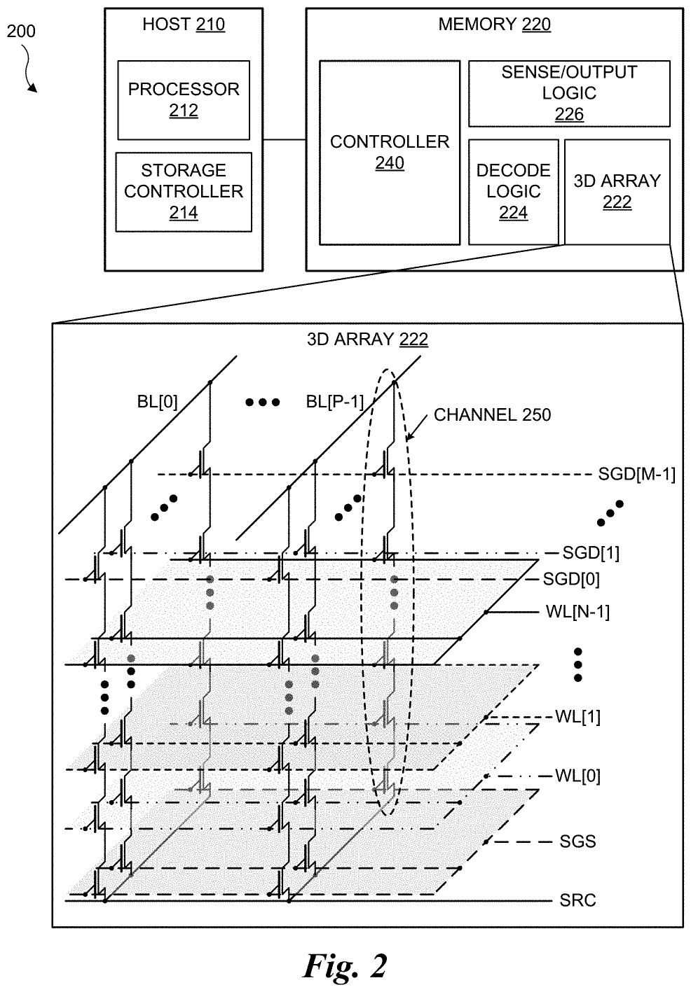

FIG. 2 is a block diagram of an example system illustrating further details of a 3D memory device structure. System 200 represents a computing device that includes a 3D memory. Host 210 represents a hardware platform that performs operations to control the functions of system 200. Host 210 includes processor 212, which is a host processor that executes the operations of the host. In one example, processor 212 is a single-core processor. In one example, processor 212 is a multicore processor device. Processor 212 can be a general-purpose processor that executes a host operating system or a software platform for system 200. In one example, processor 212 is an application specific processor, a graphics processor, a peripheral processor, or other controller or processing unit on host 210. Processor 212 executes multiple agents or software programs (not specifically shown). The agents can be standalone programs and/or threads, processes, software modules, or other code and data to be operated on by processor 212.

During execution of operations by processor 212, an agent executed by the processor can request data and/or code that is not stored at host 210 (e.g., in a cache or main memory), and therefore should be obtained from memory 220. Storage controller 214 generates and processes memory access commands to memory 220 to perform the memory access. Storage controller 214 represents a circuit or logic or processor that manages access to memory 220. In one example, storage controller 214 is part of host 210. In one example, storage controller 214 is part of processor 212. In one example, storage controller 214 is integrated on a common substrate with processor 212. In one example, storage controller 214 separate chip from processor 212, and can be integrated in a multichip package (MCP) with processor 212.

Memory 220 includes controller 240, which represents a controller at the memory or storage device to process and service commands from storage controller 214. In one example, controller 240 represents a controller for a memory device. In one example, controller 240 represents a controller for a memory module. Memory 220 includes 3D array 222. In one example, 3D array 222 includes NAND memory blocks. In one example, 3D array 222 includes QLC NAND memory blocks.

As illustrated, bitlines (BL) intersect the planes of the tiers of wordlines (WL). As an example, each wordline WL[0:(N-1)] is a tier. There can be P bitlines (BL[0:(P-1)]). In one example, 3D array 222 is also divided into subblocks through SGD[0:(M-1)], which divide each wordline into separate segments within a tier or within a plane of wordlines. Alternatively, SGS can be subdivided to provide subblocks. In such a configuration, whereas SGS is shown to apply to multiple SGD lines, there could be multiple SGS lines to a single SGD line. SRC represents a common source.

Channel 250 represents a vertical channel of the 3D array. The channel refers to a vertical stack of bitcells that can be charged through a channel connector. In one example, the channels couple to the bitline. It will be understood that there can be spatial dependencies in the stable Vt state of a channel. For example, the flow of charge carriers in the channel can be different at the different ends of the channels. Thus, blocks with specific wordlines may show worse degradation than others. The operation of controller 240 to mitigate read disturb due to stable Vt in the channel can be set by thresholds and operation that mitigates the most sensitive of the wordlines.

Each label, WL[0], WL[1], SGD[0], and so forth, indicates a select signal provided by control logic of decode logic 224, or a select signal provided by control logic of sense/output logic 226. In one example, decode logic 224 includes selection logic to select each of the signal lines illustrated. In one example, sense/output logic 226 enables the sensing of the contents of bitcells of 3D array 222, for either a read operation or to write a value back to the array. The output can be for a read operation to send data back to host 210. A write operation would include writing to a buffer to apply the values to the array.

It will be understood that a signal line in 3D array 222 is a wire or trace or other conductor that provides charge from a driver to the various elements or components. A driver circuit decode logic 224 provides the charge to charge up each signal line to the desired voltage for the desired operation. Each signal line can have an associated voltage level associated with certain operations. For example, each wordline can have a select voltage and a deselect voltage to indicate, respectively, wordlines that are selected for an operation and wordlines that are not selected for an operation.

In 3D array 222, it will be understood that the length of the wordlines can be substantial. In one example, the number of tiers of wordlines is on the order of tens or dozens of wordlines (e.g., N=28, 32, 36, 70, or more). In one example, the number of subblocks is on the order of ones or tens (e.g., M=8, 76, or more). Typically, the number of bitlines in 3D array 222 will be on the order of hundreds to thousands (e.g., P=2K). Thus, in one example, each bitline is relatively short compared to the length of the wordlines.

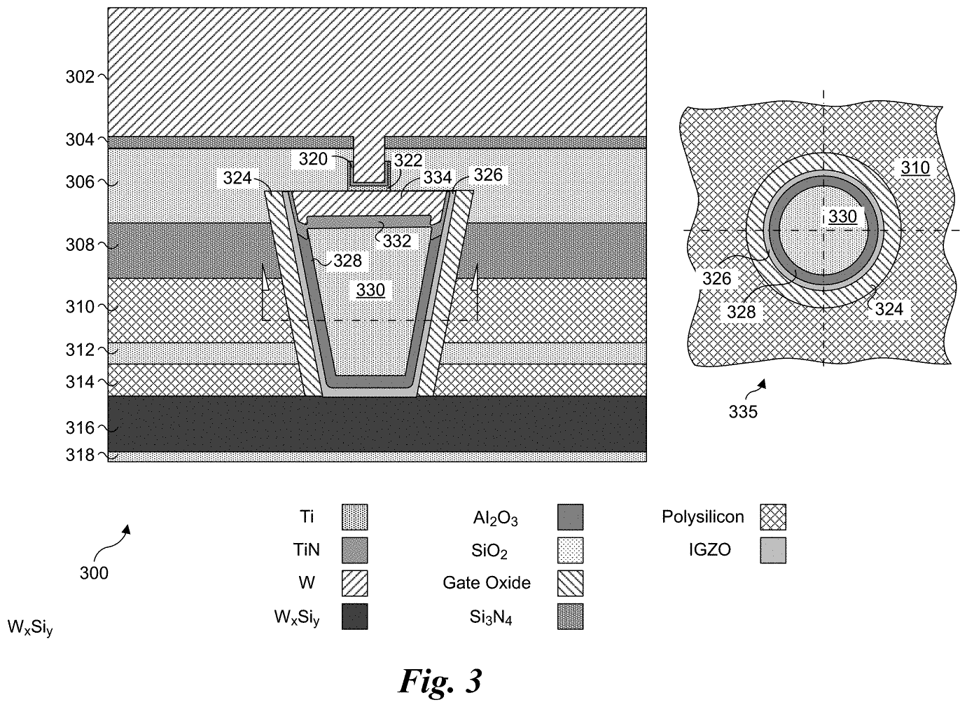

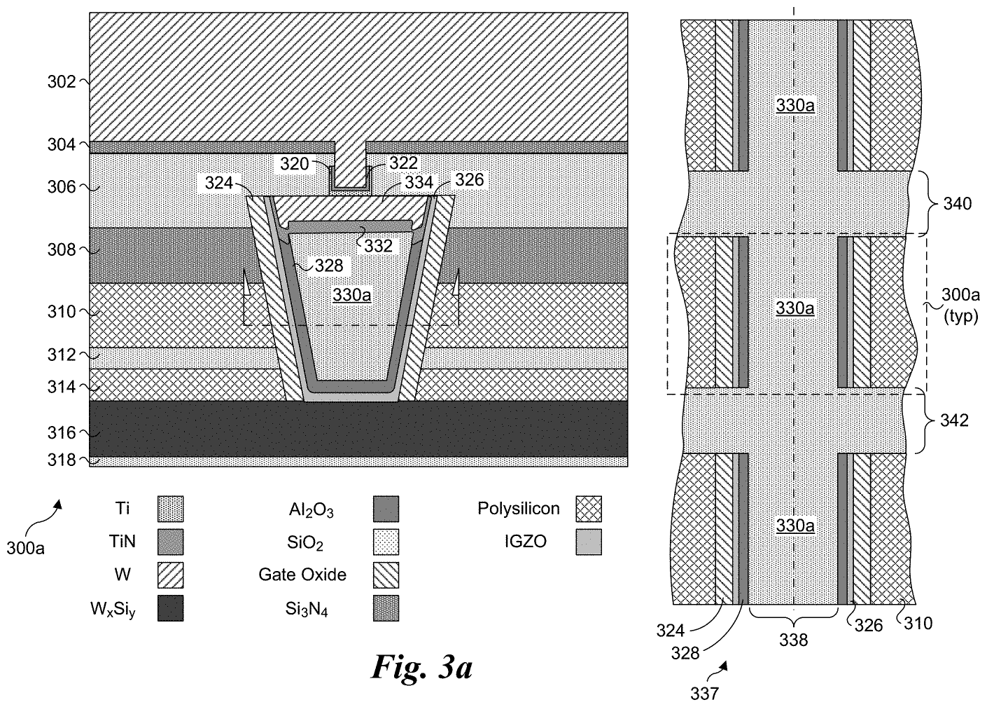

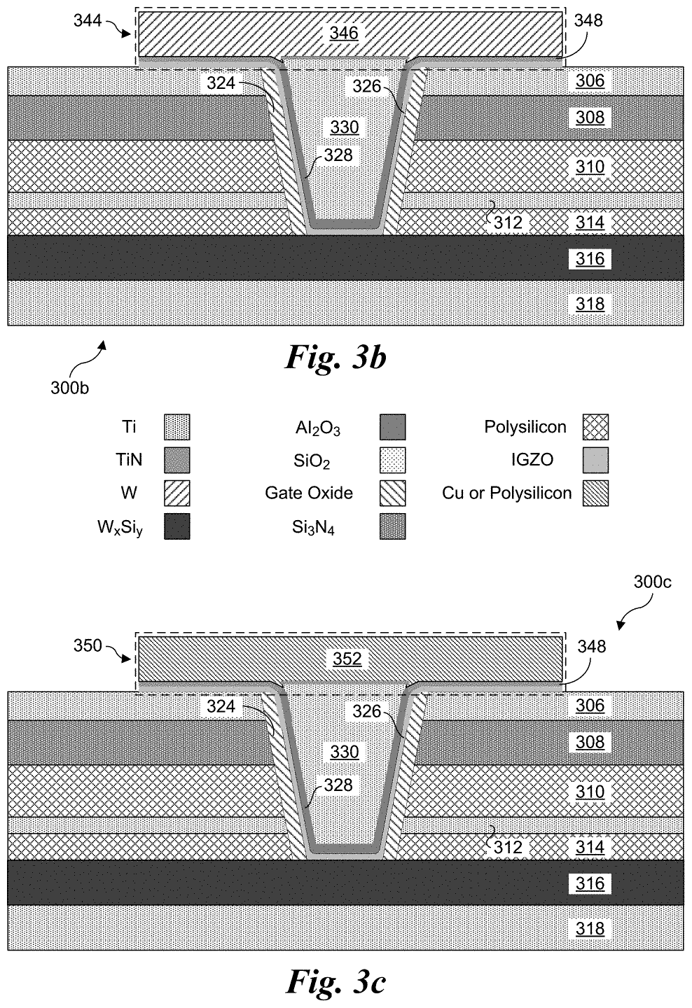

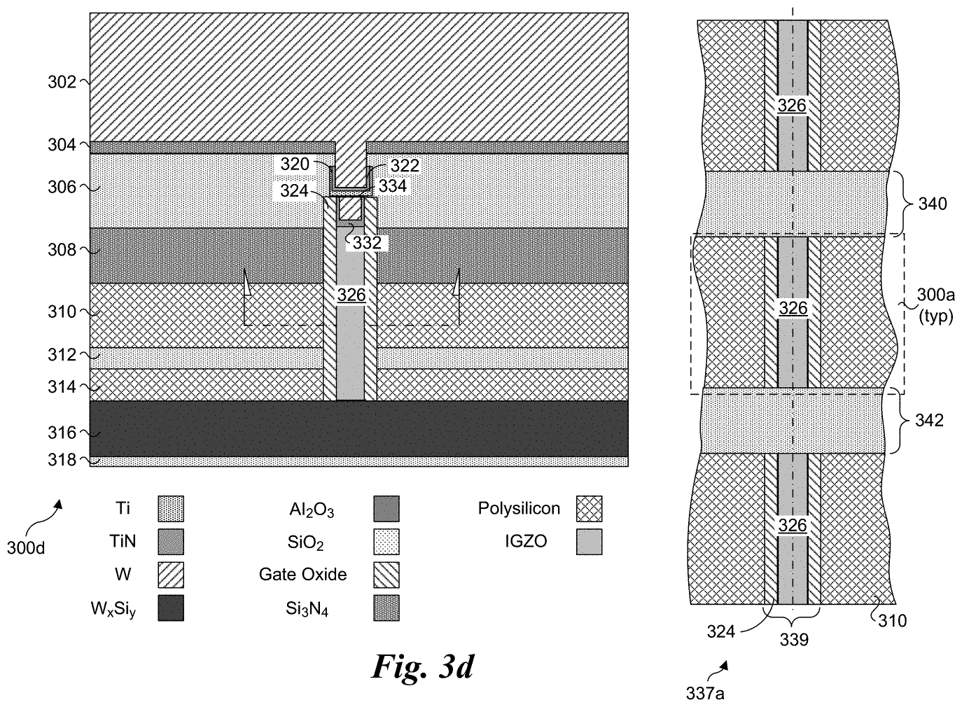

FIG. 3 shows a transistor gate structure 300, according to one embodiment. Structure 300 comprises a gate all around (GAA) thin film transistor (TFT) device based on a p-type polysilicon gate, an amorphous IGZO (Indium Gallium Zinc Oxide) channel, an AlOₓ (aluminum oxide) liner, a deposited low temperature gate oxide, and TiN/W (titanium nitride/tungsten) contacts. In one embodiment, an existing poly-Si gate in a conventional 3D NAND structure is used. Optionally, a high workfunction metal replacement gate/multi-gate may be used. An amorphous-IGZO (wide bandgap) oxide semiconductor channel is deposited using physical vapor deposition (PVD) or atomic layer deposition (ALD) in a thickness range of 3-10 nm. The channel materials include IGZO, IAZO (Indium Aluminum Zinc Oxide), and treatments for post-thermal process stability (F-implant). An aluminum oxide dielectric channel liner is deposited under specified conditions with low H content/low-H containing precursor and below a critical thickness in order to ensure positive device Vt. In one embodiment the structure employs conventional low temperature oxide gapfill, and conventional TiN/W contacts.

The layers in structure 300 include a tungsten (W) fill 302, silicon nitride (Si₃N₄) layer 304, a silicon oxide (SiO2) layer 306, a silicon nitride layer 308, a polysilicon layer 310, a silicon oxide layer 312, a polysilicon layer 314, a WₓSi_{y} (e.g., tungsten silicide (W₅Si₃)) layer 316, and a silicon oxide layer 318. The transistor structure comprises a pillar having an inverted conical frustum shape and including a gate oxide 324 outer wall, an amorphous IGZO channel 326, an Al₂O₃ (aluminum oxide) liner 328, and an SiO₂ fill 330 over which a TiN/W contact is formed including TiN 332 cap over which a W contact 334 is formed. A TiN structure 320 and Ti structure 322 are formed above W contact 334.

As shown in the cross-section detail 335, the cross-section of the gate structure in one embodiment is circular; the diameter of the gate oxide 324 outer wall, amorphous IGZO channel 326, Al₂O₃ liner 328, and SiO₂ fill 330 will vary with the depth of the inverted conical frustum pillar. The angle of the sidewall may vary depending on the etchant that is used to form the inverted conical frustrum pillar and the materials in the layers that are being etched.

FIG. 3a shows a first alternative configuration of a transistor device having a double gate structure 300a. In this example, the elevation cross-section view on the left is depicted as being the same as for structures 300 and 300a; as illustrated in embodiments below, in addition to an inverted conical frustrum shape the pillar shape may be generally cylindrical with a straight sidewall—similarly, the double gate structure may employ angled walls (as shown in FIG. 3a) or straight walls. As shown in the detail 337, a column of double gate structures 300a is formed using a trench 338 and multiple orthogonal trenches 340 and 342. Trenches 338, 340, and 342 may be formed using known fabrication techniques, such as using an etchant.

FIGS. 3b and 3c show elevation cross-section views of transistor devices 300b and 300c having similar structures to that shown in FIG. 3, but having different top/drain contact patterns and materials. As shown in FIG. 3b, contact pattern 344 comprises a pad of tungsten 346 formed over a layer of TiN 348. Generally, in addition to tungsten, the contact pattern pad may employ a material with similar work function to tungsten. For example, in FIG. 3c contact pattern 350 comprises a pad 352 of copper or polysilicon 352 formed over a TiN layer 348, which are non-limiting examples of suitable pad materials. The shape of pads 346 and 352 may vary to accommodate different designs, but will always cover at least the top of SiO₂ fill 330.

FIG. 3d shows cross-section view of transistors devices comprising a double-gate structure 300d in which the pillars are filled with IGZO 326 without use of an (Al₂O₃) liner or SiO₂ fill. As shown in detail 337a, the width of trenches 339 prior to deposition of gate oxide 324 the IGZO fill is substantially narrow than shown in FIG. 3a and discussed above (noting the double gate embodiment shown in FIG. 3d employs straight walls).

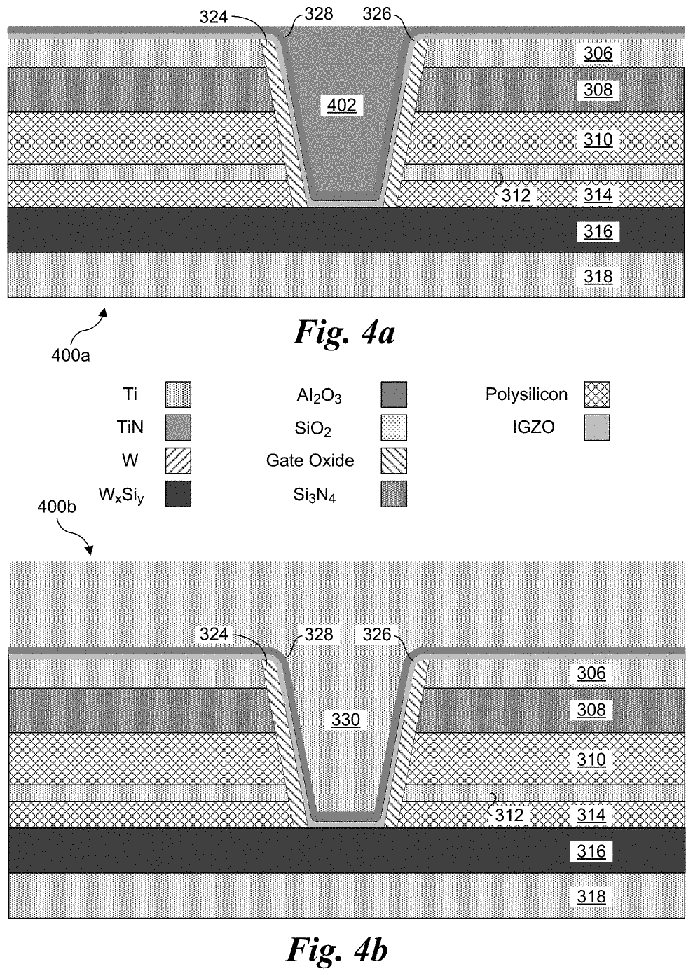

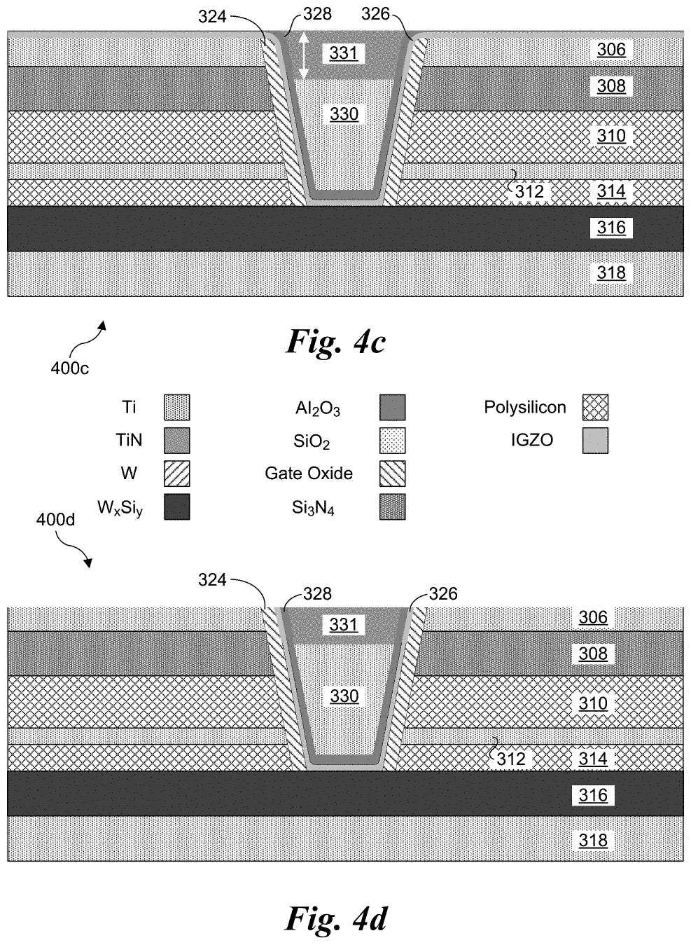

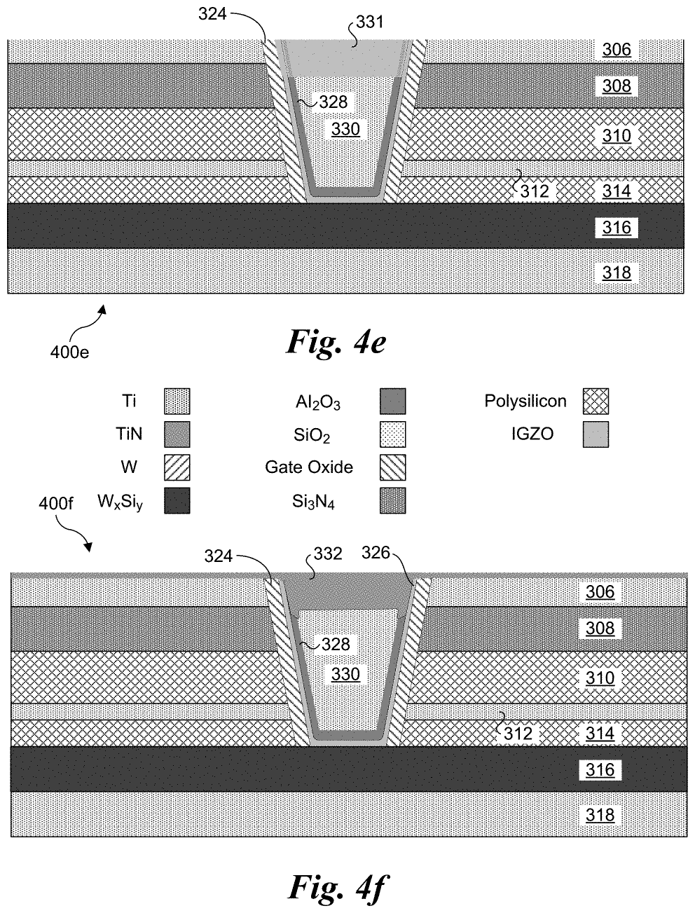

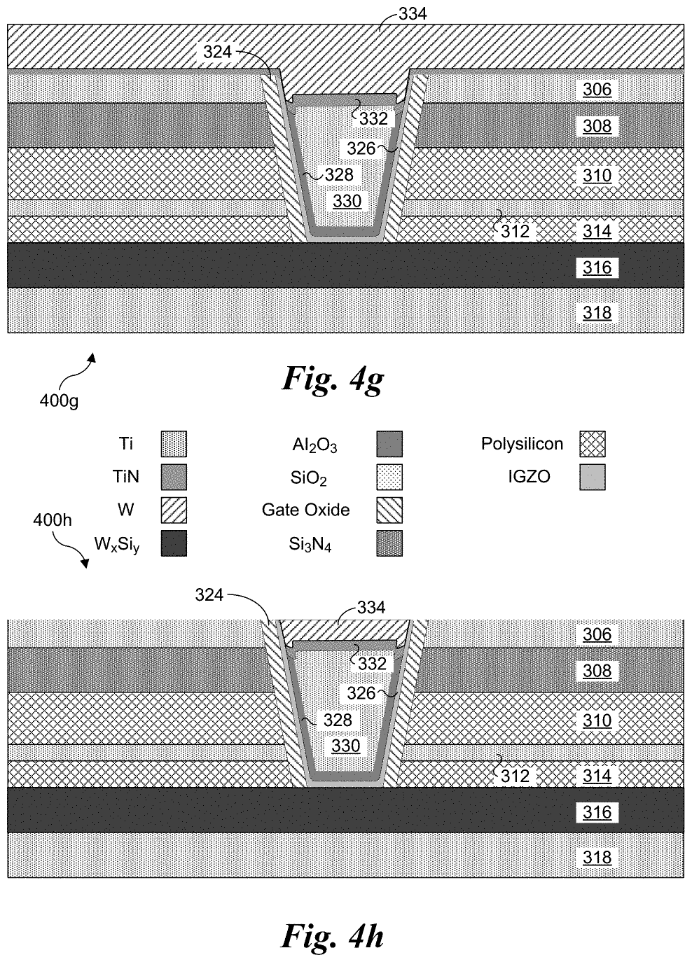

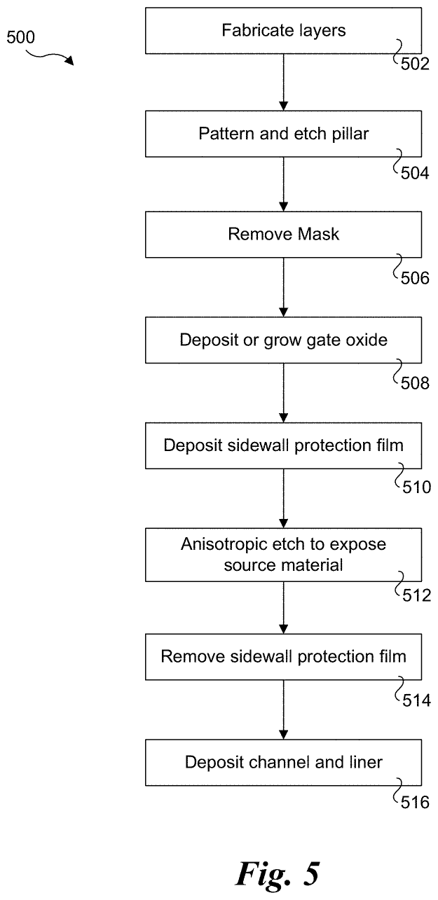

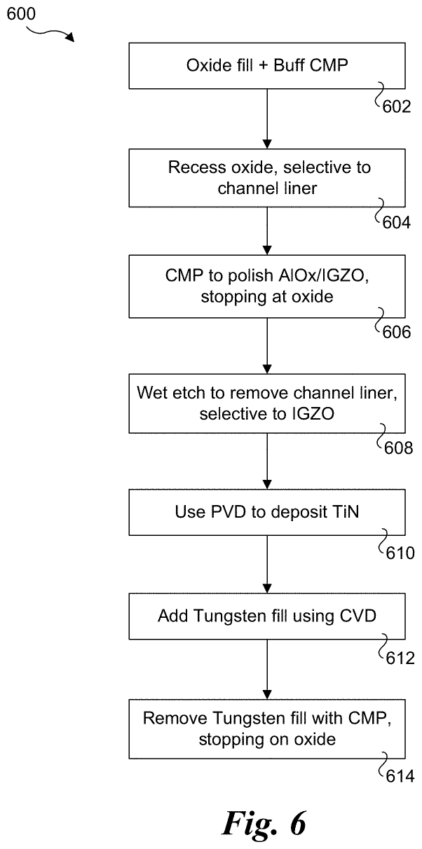

A construction sequence for fabricating transistor gate structure 300 is illustrated in FIG. 4a-4h, with operations/steps shown in flowcharts 500 and 600 of FIGS. 5 and 6. The sequence begins with an intermediate structure 400a that is formed using the process of flowchart 500, which begins in a step 502 by fabricating the layers. The fabrication operations may use known techniques for fabricating the layers, such as depositing or otherwise forming the layers shown, beginning with silicon oxide layer 318, followed by WₓSi_{y} layer 316, polysilicon layer 314, silicon oxide layer 312, polysilicon layer 310, silicon nitride layer 308, and silicon oxide layer 306. Next, in a step 504 of pattern of pillars are formed using etching. A pattern of pillars including a pillar 402 is formed in the layered structure using a mask and etching. In a step 506 the mask is removed. In a step 508 a layer of gate oxide (e.g., SiO₂) is deposited over the inner sidewall of pillar 402.

Next, in a step 510 a material is added to protect the sidewall oxide, such as a protection film of amorphous silicon. In a step 512 an anisotropic etch is performed to expose the source material (WₓSi_{y} layer 316). The sidewall protection material is removed in a step 514, and a channel and liner are deposited in a step 516. This includes depositing a layer of IGZO over the gate oxide to form the IGZO channel 326, followed by depositing a layer of AlOx to form liner 328.

Moving to flowchart 600 of FIG. 6, the following steps/operations are performed with reference to the structure 400b-400h in FIGS. 4b-4h. In a step 602, an oxide fill operation is performed with buffing using chemical-mechanical planarization (CMP). During this step, a fill of silicon oxide 330 is added. Next, in a step 604 a dry etch recess of oxide is performed. As shown in FIG. 4c, a structure 400c is obtained by etching a recess 331 in the silicon oxide selective to the channel liner. In one embodiment, recess 331 has a depth of approximately 1100A. In a step 606, CMP is used to polish the AlOx and IGZO deposited over the top of silicon oxide layer 306, stopping at the top of this layer. The result of this step is shown in structure 400d of FIG. 4.

Next, in a step 608 a wet etch is performed to remove AlOx channel liner using NH₄OH (ammonium hydroxide solution, also called ammonia solution, ammonia aqueous or ammonia water), leaving an annular hoop of IGZO 326, as shown in structure 400e of FIG. 4e. In a step 610, the void obtained via the wet etch in step 608 is then filled with TiN 332 using PVD to obtain the structure 400f shown in FIG. 4f.

Continuing at a step 612, a tungsten fill 334 is added using CVD to obtain a structure 400g shown in FIG. 4g. The process is completed in a step 614 during which the tungsten fill is removed using CMP, stopping at silicon oxide layer 306 to obtain a structure 500h shown in FIG. 4h. Subsequent operations not separately shown are then performed to obtain the transistor gate structure 300 shown in FIG. 3 using know conventional techniques.

In one embodiment, the silicon oxide layers are deposited as silicon oxide films using Tetraethyl orthosilicate (TEOS), which has a chemical formula SiC₈H₂₀O₄. In one embodiment, the silicon nitride layers 304 and 308 are deposited using low-pressure chemical vapor deposition (LPCVP).

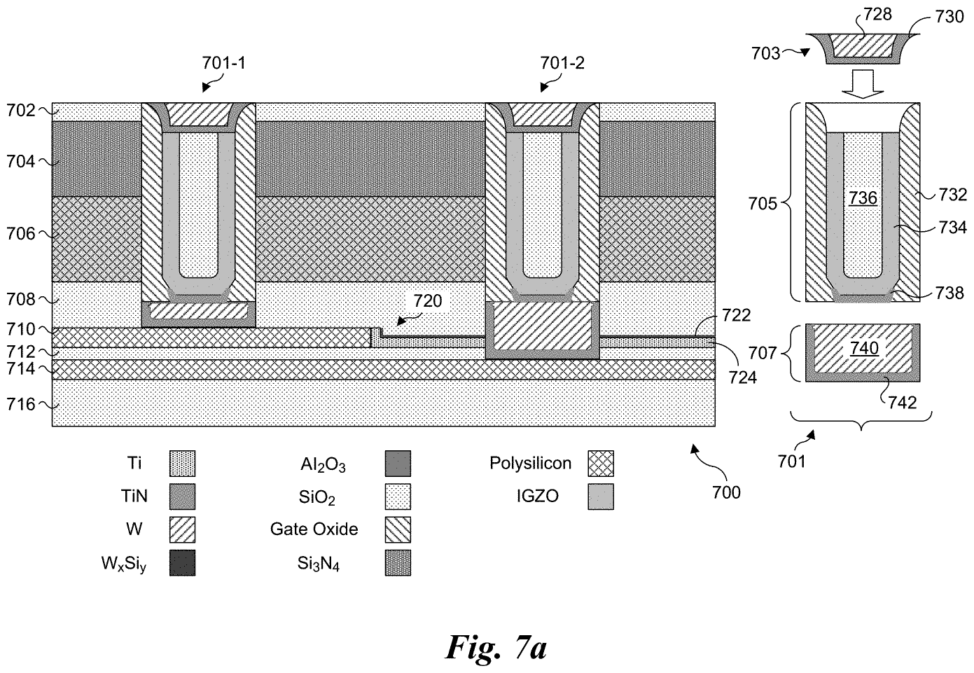

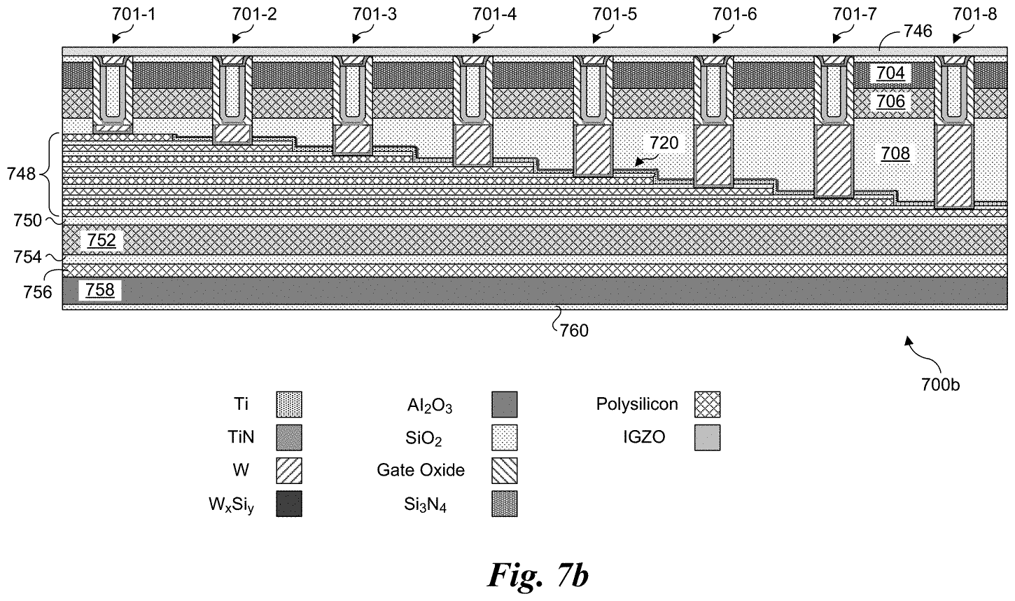

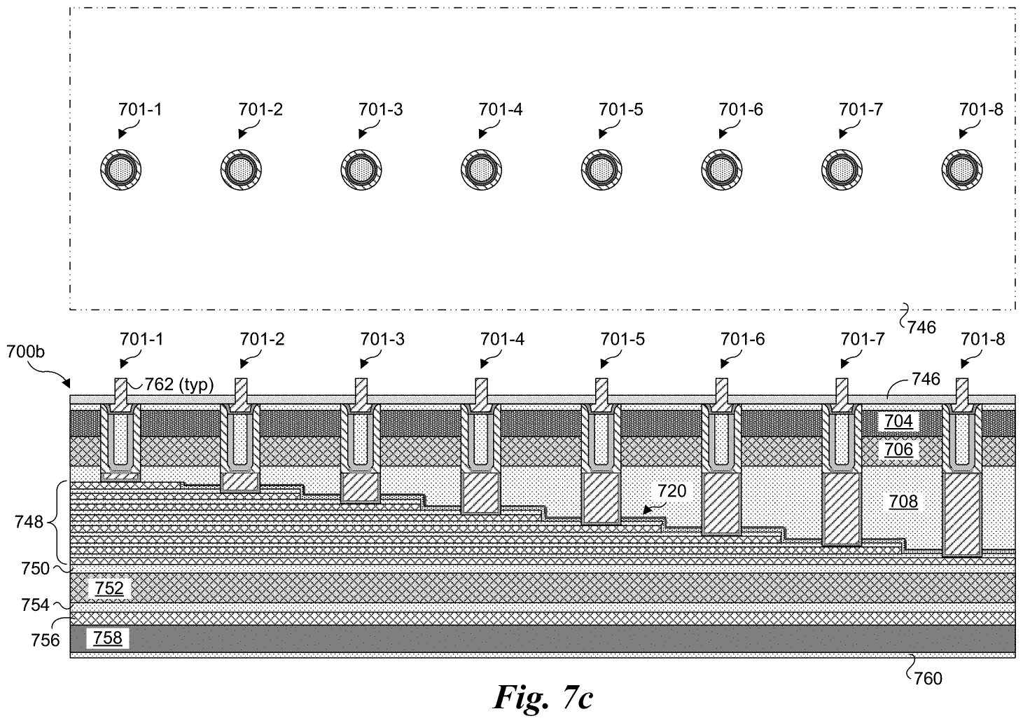

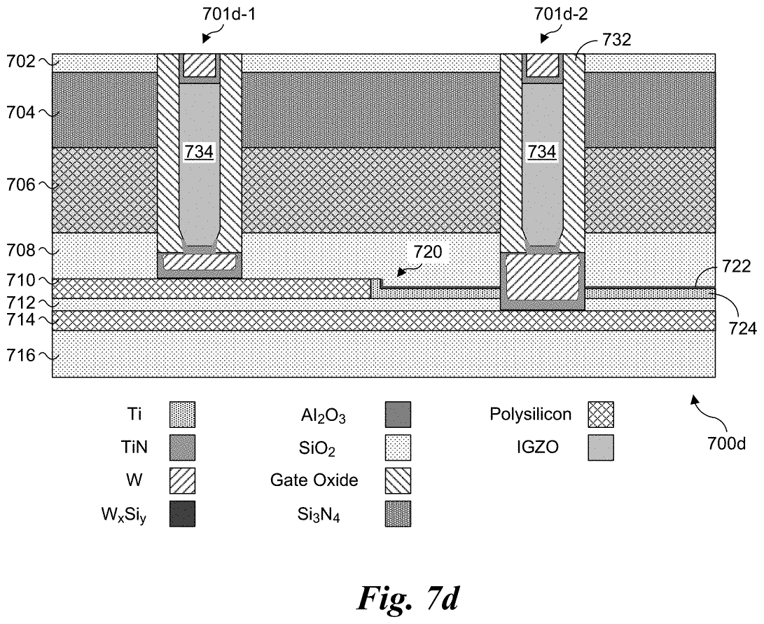

FIG. 7a shows a portion of a semiconductor structure 700 in which two GAA TFT devices 701-1 and 701-2 having a first alternative configuration are shown. The layer structure of the semiconductor substrate includes a silicon oxide layer 702, a silicon nitride layer 704, a polysilicon layer 706, a silicon oxide layer 708, first and second wordlines 710 and 714, and silicon oxide layers 712 and 716. First wordline 710 includes a “staircase structure 720 comprising a pattern of silicon nitride 722 formed over a pattern of IGZO 724.

As shown in the upper right-hand portion of FIG. 7a, a GAA TFT device 701 includes an upper W/TiN contact 703 comprising W 728 and TiN 730 formed above a pillar 705 having a straight wall including a gate oxide outer wall 732, an IGZO channel 734, and a silicon oxide core 736. A W/TiN wordline contact 707 comprising W 740 and TiN 742 is formed below pillar 705. A TiN structure 738 comprising an optional bottom contact conductive liner may be disposed between a base portion of IGZO channel 734 and W/TiN wordline contact 707 in some embodiments.

FIG. 7b shows a cutaway view of a portion of a semiconductor device 700b that includes either GAA TFT devices 701-1, 701-2, . . . 701-8. Semiconductor device 700b generally comprises the layer structure shown for semiconductor structure 700 in FIG. 7a above with additional layers and structures including an SiO₂ layer 746 and wordlines 748, which comprise polysilicon with a layer of silicon oxide disposed between wordlines 748. The additional layers below wordlines 748 include a silicon oxide layer 750, 754, and 760, polysilicon layers 752 ad 756, and an aluminum oxide layer 758. FIG. 7b also shows further details of the staircase structure 720, which includes a step-down for each respective GAA TFT device 701-1, 701-2, . . . 701-8. Also, the lower W/TiN contact portion of the respective GAA TFT devices 701-1, 701-2, . . . 701-8 is increasingly taller to provide a connection between a given GAA TFT device 701 and a respective wordline 748.

FIG. 7c adds a plan view (upper portion of Figure) to what is shown in FIG. 7b. Persons of skill in the art will recognize that an actual semiconductor device, such as but not limited to a 3D NAND device, would have sets of GAA TFT devices 701 coupled to respective wordlines 740 disposed in multiple layers. For example, see FIG. 11 below. This includes material 762 (e.g., Tungsten in the illustrated embodiment) that would be coupled to signal routing formed in a layer or layers above the layered structure shown in FIGS. 7b and 7c.

FIG. 7d shows a portion of a semiconductor structure 700d that includes double gate transistor devices 701d-1 and 701d-2 having a pillar structure employing an amorphous IGZO core 734 comprising the channel without using a silicone oxide core such as that shown in FIG. 7a. In a manner similar to double gate structure 300d in FIG. 3d, the width of the trenches etched prior to depositing gate oxide 732 and IGZO fill is narrower than the trenches used for double gate structures that would employ a liner and a silicon oxide fill.

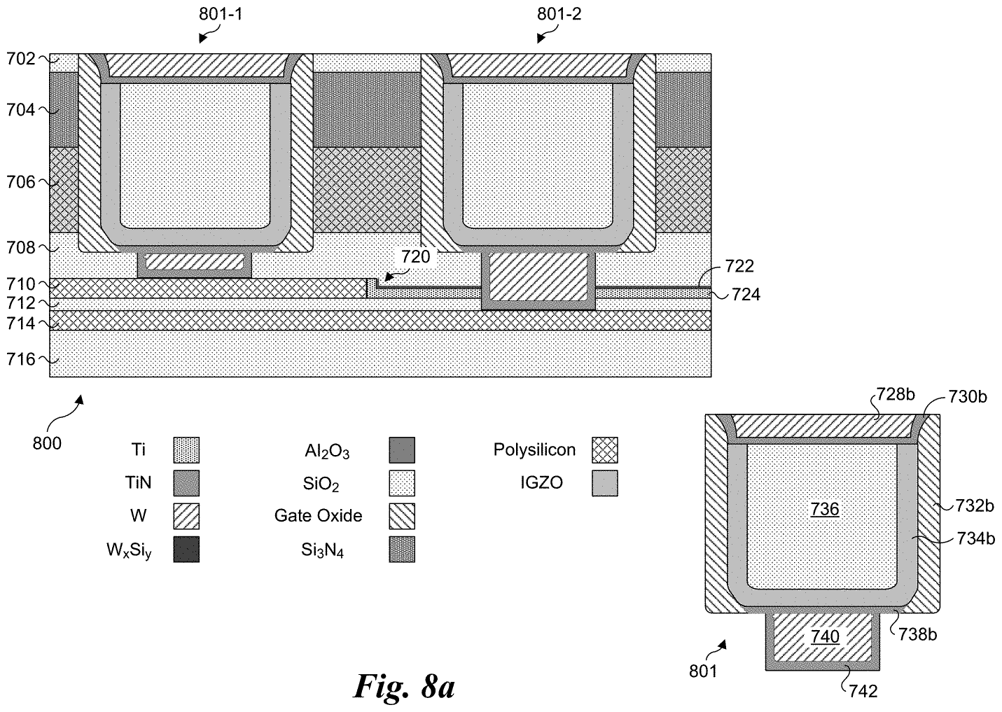

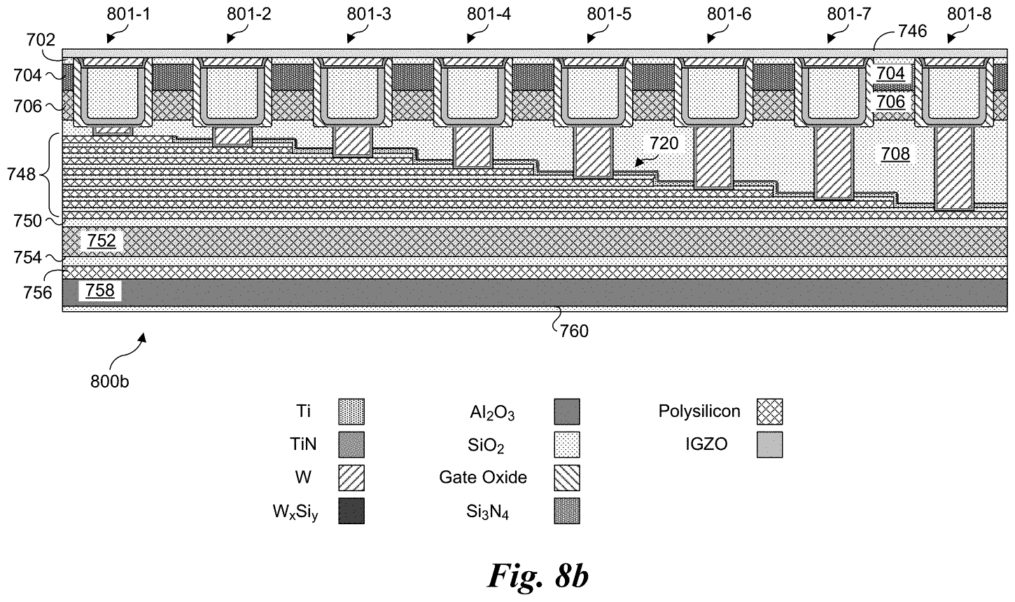

FIGS. 8a and 8b respectively show a semiconductor structure 800 and a cutaway view of a portion of a semiconductor device 800b that includes GAA TFT devices 801 that are a first variant of GAA TFT devices 701. As shown by like-numbered layers and components, structures of semiconductors structures 700 and 800 are generally similar, with the difference being the diameter of the GAA TFT devices 701 and 801. As shown in the detailed view at lower right portion of FIG. 8a, GAA TFT devices 801 include an upper W/TiN contact comprising W 728b and TiN 730b formed above a pillar having a straight wall including a gate oxide outer wall 732b, an IGZO channel 734b, and a silicon oxide core 736b. As with GAA TFT devices 701, a TiN structure 738 is disposed between a base of IGZO channel 734 and a lower contact W/TiN contact comprising W 740 and TiN 742.

Generally, the layers and structures in semiconductor devices 700b and 800b are similar, as indicated by like reference numbers. The notable different is GAA TFT devices 801 (801-1, 801-2, . . . 801-8) have replaced GAA TFT devices 701 (701-1, 701-2, . . . 701-8) in semiconductor device 800b.

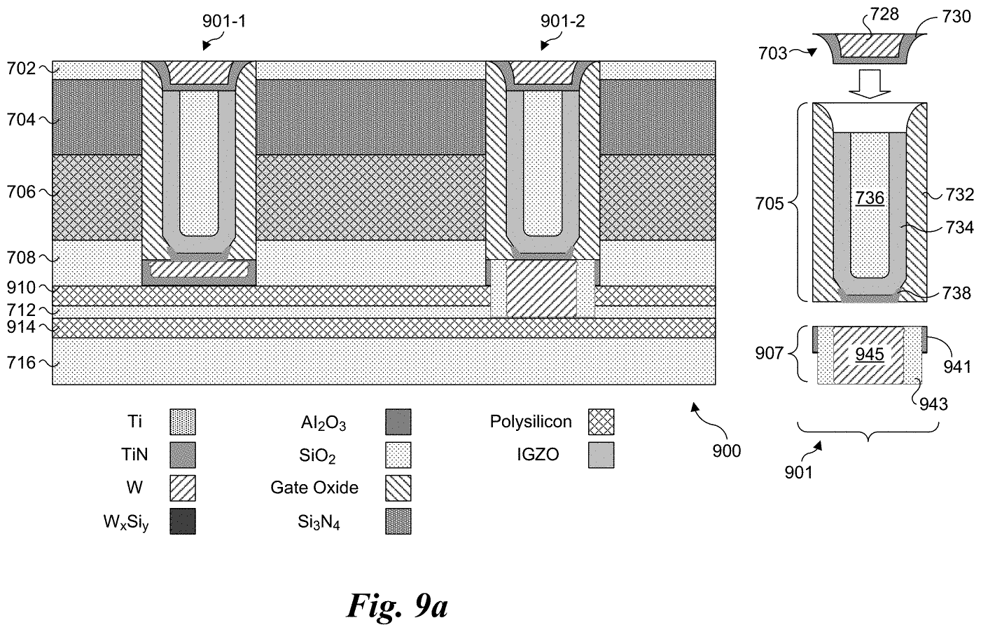

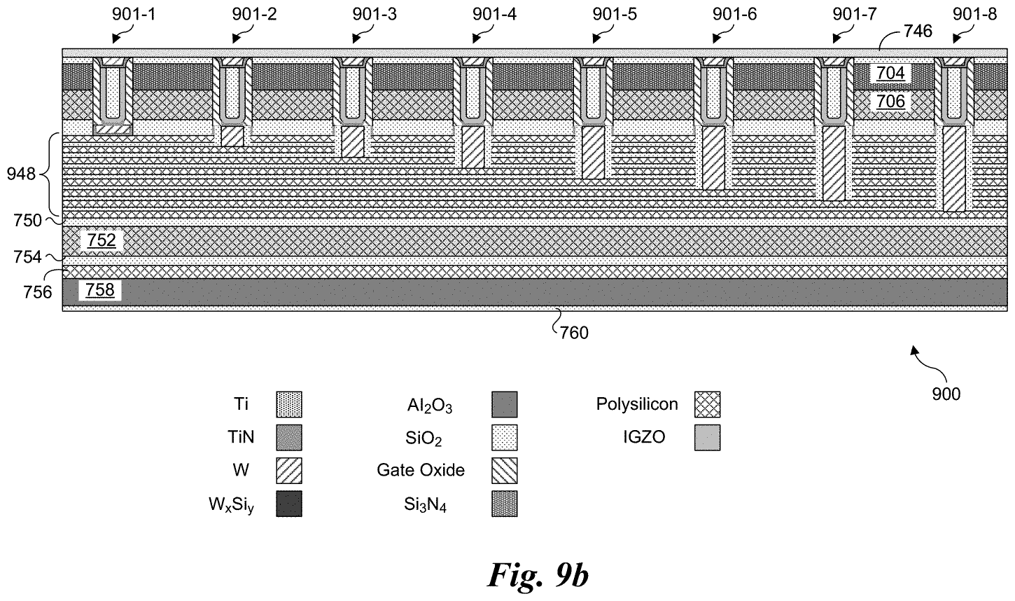

FIGS. 9a and 9b respectively show a semiconductor structure 900 and a cutaway view of a portion of a semiconductor device 900b that includes GAA TFT devices 901 that are a second variant of GAA TFT devices 701. Generally, as shown by layers and structures with the same reference numbers in semiconductor structure 700 and 900, most of the structures are similar. However, under semiconductor structure 900, the wordline contacts 907 of GAA TFT devices 901 (901-1, 901-2, . . . 901-8) are extended to contact a respective wordline, as depicted by wordlines 910 and 914 in FIG. 9a. As shown in the detail view of GAA TFT device 901, the structure for upper W/TiN contact 703 and pillar 705 are the same as for semiconductor structure 700 shown in FIGS. 7a and 7b above. The difference is the structure of the wordline contact 907, which comprises a TiN shoulder 941, coupled to a pillar comprising an SiO₂ insulating liner 943 having a tungsten fill 945. As shown in FIG. 9b, wordlines 948 are formed using respective polysilicon layers separated by SiO₂ layers. The wordline contacts 907 for GAA TFT devices 901-1, 901-2, . . . 901-8 have different vertical lengths that extend to a respective wordline 948.

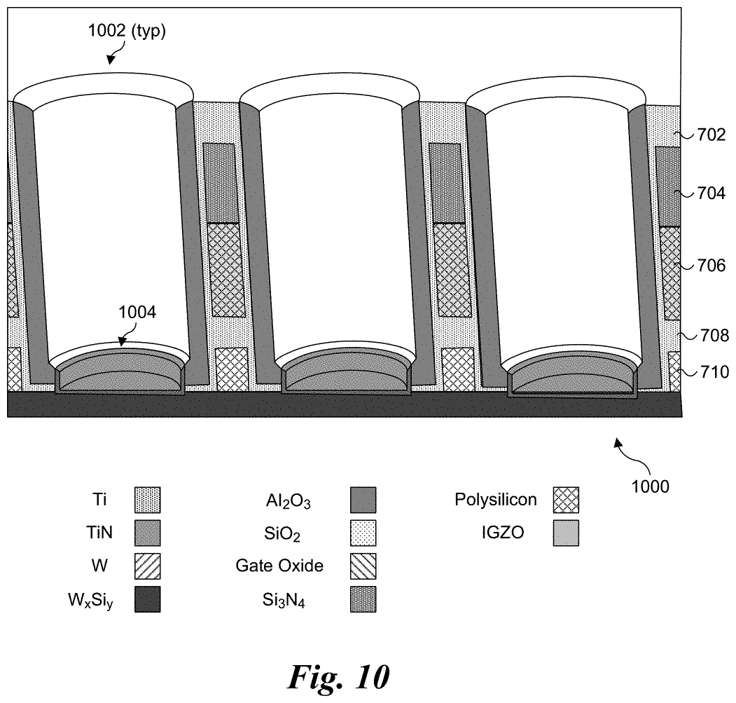

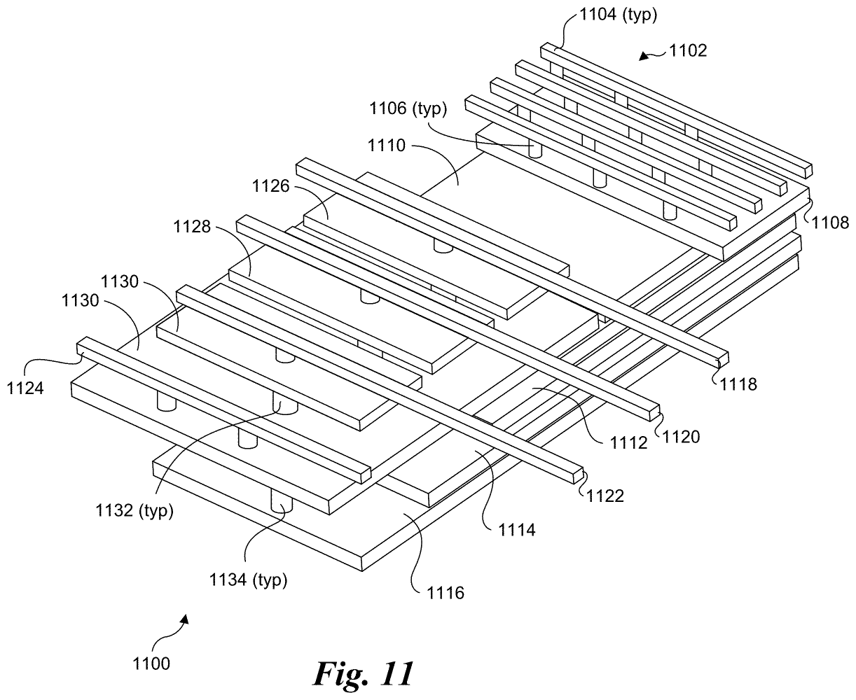

FIG. 10 shows a semiconductor structure 1000 including transistor device 1002 that have a TiN bottom plug contact 1004. Generally, the layers and structures in semiconductor substrate 1000 are similar to those shown for semiconductor structure 700 and 900, except for the TiN bottom plug contact, which is shown with an alternative structure.

Various figures herein show TiN drawn on the bottom-side contact. However, this is merely illustrative and non-limiting, as the use of TiN on the bottom-side contact is optional as some embodiments (not separately shown) do not employ such metal liner film.

FIG. 11 shows a 3D view of an abstracted memory device 1100. The memory device includes a 3D array 1102 have a structure similar to 3D array 222 shown in FIG. 2 and discussed above. For simplicity, the components for 3D array 1102 are depicted as bitlines 1104 coupled to pillars 1106, an SGD layer 1108, and wordlines 1110, 1112, 1114, and 1116. Memory device 1100 further includes drain-routing lines 1118, 1120, and 1122, a vertical wordline driver gate 1124, drain pads 1126, 1128, and 1130, vertical wordline drivers 1132, wordline contacts 1134, and an SGD layer 1136. As will be recognized by those skilled in the art, an actual memory device would have similar components and structures repeated many times. Moreover, the internal structures of a memory device based on the teaching and principles disclosed herein may have a configuration similar to any of the embodiments described and illustrated herein, as well as variants employing combinations of features of the illustrated embodiments.

Aspects of the figures and diagrams shown herein are simplified for illustrative purposes and ease of explanation. The transistor structures are also not drawn to scale, and representative of a higher number of similar transistor structure in actual devices. As will be recognized by those skilled in the art, such devices will generally employ high wordline counts (e.g., in the hundreds), and large arrays of memory cells in a 3D structure.

In the foregoing embodiments, the liner materials are illustrative of some exemplary and non-limiting materials that may be used as a liner. More generally, the liners comprise a film with the following considerations: low hydrogen content, need to avoid absorption of H₂O during processing, thickness is important to have stable device Vt due to fixed charges in the film, and provide a hermitic seal to prevent any interaction between IGZO and downstream steps.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A vertical wordline driver comprising:
a vertical transistor structure formed in a semiconductor substrate comprising a gate all around (GAA) structure or a double-gate structure including,
an outer member or wall comprising a gate oxide;
an amorphous IGZO (Indium Gallium Zinc Oxide) channel, adjacent to the gate oxide;
a liner, adjacent to the amorphous IGZO channel; and
a dielectric fill material.

2. The vertical wordline driver of claim 1, wherein the vertical transistor structure comprises a conical frustrum shape.

3. The vertical wordline driver of claim 1, wherein the vertical transistor structure comprises a generally cylindrical shape having a straight sidewall.

4. The vertical wordline driver of claim 1, wherein the vertical transistor structure comprises pairs of walls deposed opposite of one another, each wall comprising an outer portion of gate oxide, a middle portion of amorphous IGZO, and an inner portion of liner material, the walls being angled or straight.

5. The vertical wordline driver of claim 1, wherein the semiconductor substrate includes a plurality of stacked layers including a layer of polysilicon comprising a gate that is in contact with a portion of the gate oxide.

6. The vertical wordline driver of claim 1, wherein the liner comprises an Aluminum oxide or a Hafnium oxide.

7. The vertical wordline driver of claim 1, wherein the vertical transistor structure is employed as a wordline driver in a three-dimensional (3D) NAND device.

8. The vertical wordline driver of claim 1, further comprising a metal contact disposed above and electrically coupled to the amorphous IGZO channel.

9. The vertical wordline driver of claim 1, further comprising a wordline contact disposed below the amorphous IGZO channel and electrically coupling the amorphous IGZO channel to a respective wordline formed in the semiconductor substrate.

10. The vertical wordline driver of claim 1, further including a bottom plug contact comprising a metallic alloy disposed the vertical structure.

11. A three-dimensional (3D) memory device, comprising:
a semiconductor substrate including a plurality of layers;
a plurality of wordlines formed in a 3D stack of multiple tiers;
a plurality of vertical wordline drivers, each comprising,
a vertical transistor structure formed in the semiconductor substrate comprising a gate all around (GAA) structure or a double-gate structure including,
an outer member or wall comprising a gate oxide;
an amorphous IGZO (Indium Gallium Zinc Oxide) channel, adjacent to the gate oxide;
a liner, adjacent to the amorphous IGZO channel;
a dielectric fill material;
an upper contact, electrically coupled to the amorphous IGZO channel; and
a lower contact, electrically coupled to a respective wordline.

12. The 3D memory device of claim 11, wherein the 3D memory device comprises a 3D NAND memory device.

13. The 3D memory device of claim 11, wherein the plurality of layers in the semiconductor substrate includes a polysilicon layer that is in contact with the gate oxide and is used as a gate.

14. The 3D memory device of claim 11, wherein the vertical transistor structure comprises a pillar having a conical frustrum shape or a cylindrical shape with a straight sidewall.

15. The 3D memory device of claim 11, wherein the vertical transistor structure comprises pairs of walls deposed opposite of one another, each wall comprising an outer portion of gate oxide, a middle portion of amorphous IGZO, and an inner portion of liner material, the walls being either angled or straight.

16. A system comprising:
A host apparatus including a storage controller operatively coupled to one or more memory modules having at least one three-dimensional (3D) memory device, comprising,
a semiconductor substrate including a plurality of layers;
a plurality of wordlines formed in a 3D stack of multiple tiers;
a plurality of vertical wordline drivers, each comprising,
a vertical transistor structure formed in the semiconductor substrate comprising a gate all around (GAA) structure or a double-gate structure including,
a gate oxide;
an amorphous IGZO (Indium Gallium Zinc Oxide) channel, adjacent to the gate oxide;
a liner, adjacent to the amorphous IGZO channel;
a dielectric fill material;
an upper contact, electrically coupled to the amorphous IGZO channel; and
a lower contact, electrically coupled to a respective wordline.

17. The system of claim 16, wherein the host apparatus comprises a system on a chip (SoC) or System on Package (SoP) including a processor operatively coupled to the storage controller.

18. The system of claim 16, wherein the at least one 3D memory comprises a 3D NAND memory device.

19. The system of claim 16, wherein the vertical transistor structure comprises a pillar having a conical frustrum shape or a cylindrical shape with a straight sidewall.

20. The system of claim 16, wherein the vertical transistor structure comprises pairs of walls deposed opposite of one another, each wall comprising an outer portion of gate oxide, a middle portion of amorphous IGZO, and an inner portion of liner material, the walls being either angled or straight.
